(19) United States
(12) Patent Application Publication
(10) Pub. No.: US 2025/0183863 A1
(43) Pub. Date: Jun. 5, 2025

(54) TRANSCONDUCTANCE AMPLIFIER CIRCUIT AND DC-DC CONVERTER USING THE TRANSCONDUCTANCE AMPLIFIER CIRCUIT

(71) Applicant: MEDIATEK INC., Hsinchu City (TW)

(72) Inventors: Shao-Huan HUNG, Hsinchu City (TW); Shao Siang NG, Hsinchu City (TW); Chia-Hua CHOU, Hsinchu City (TW)

(21) Appl. No.: 18/956,356

(22) Filed: Nov. 22, 2024

Related U.S. Application Data
(60) Provisional application No. 63/604,248, filed on Nov. 30, 2023.

(51) Int. Cl. H03F 3/45; H02M 3/158

(52) U.S. Cl. CPC H03F 3/45475; H02M 3/158; H03F 3/45273; H03F 3/45636; H03F 2203/45022

(57) ABSTRACT

A transconductance amplifier circuit with wide input range and high linearity is shown. The transconductance amplifier circuit includes a voltage-to-current circuit having first and second input metal-oxide-semiconductor field-effect transistors (MOSs), first and second output MOSs, a resistor coupled between the drains of the output MOSs, and first and second non-inverting circuits. A differential voltage input is coupled to the gates of the first and second input MOSs. A differential current output is generated at the sources of the first and second output MOSs. The drains of the first and second output MOSs are coupled to the sources of the first and second input MOSs, respectively. The drain of the first input MOS is coupled to the gate of the first output MOS through the first non-inverting circuit, and the drain of the second input MOS is coupled to the gate of the second output MOS through the second non-inverting circuit.

### CROSS REFERENCE TO RELATED APPLICATIONS

This application claims the benefit of U.S. Provisional Application No. 63/604,248, filed Nov. 30, 2023, the entirety of which is incorporated by reference herein.

### BACKGROUND OF THE INVENTION

### Field of the Invention

The present invention relates to a transconductance amplifier circuit applied to a type-II compensator circuit of a DC-DC converter.

### Description of the Related Art

FIG. 1 illustrates a block diagram of a negative feedback control loop that implements a switched-inductor based DC-DC converter 100. The inductor current information is compensated by the negative feedback generated by a compensator circuit (with a transfer function β(s)) based on the output voltage Vo, and then is transformed through the transfer function A(s) of the basic switched-inductor DC-DC conversion circuit to modulate the output voltage Vo.

The components within the compensator circuit (β(s)) may be sensitive to process, voltage and temperature (PVT) variations. How to build a PVT insensitive DC-DC converter is called for in this technical field.

### BRIEF SUMMARY OF THE INVENTION

A wide input range and high linearity transconductance amplifier circuit applied to a type-II compensator circuit of a DC-DC converter is shown.

In an exemplary embodiment, a transconductance amplifier circuit in accordance with an exemplary embodiment of the disclosure includes a voltage-to-current (V-to-I) circuit. The V-to-I circuit includes first input metal-oxide-semiconductor field-effect transistor (MOS), a second input MOS, a first output MOS, a second output MOS, a resistor, a first non-inverting circuit, and a second non-inverting circuit. A differential voltage input is coupled to the V-to-I circuit through the gate of the first input MOS and the gate of the second input MOS. A differential current output is generated at the source of the first output MOS and the source of the second output MOS. The resistor is coupled between the drain of the first output MOS and the drain of the second output MOS. The drain of the first output MOS is coupled to the source of the first input MOS, and the drain of the second output MOS is coupled to the source of the second input MOS. The drain of the first input MOS is coupled to the gate of the first output MOS through the first non-inverting circuit, and the drain of the second input MOS is coupled to the gate of the second output MOS through the second non-inverting circuit. The first and second non-inverting circuits make the input range wide, and the improve the circuit linearity.

In an exemplary embodiment, the transconductance amplifier circuit further comprises a current summing circuit. The current summing circuit receives the differential current output from the voltage-to-current circuit, and generates an amplified voltage.

In an exemplary embodiment, a DC-DC converter using the transconductance amplifier circuit is shown. The DC-DC converter includes a basic switched-inductor DC-DC conversion circuit, and a type-II compensator circuit using the transconductance amplifier circuit. The type-II compensator circuit is coupled to the basic switched-inductor DC-DC conversion circuit to form a negative feedback control loop, and introduces two poles and one zero. The resistor of the transconductance amplifier circuit and a compensation resistor are manufactured by the same type of process.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 illustrates a block diagram of a negative feedback control loop that implements a switched-inductor based DC-DC converter 100;

FIG. 2 depicts a switched-inductor based DC-DC converter 200 in accordance with an exemplary embodiment of the disclosure, which includes a basic switched-inductor DC-DC conversion circuit 202 (with a transfer function A(s)) and a type-II compensator circuit (with a transfer function β(s));

FIG. 3 is a Bode diagram of the switched-inductor based DC-DC converter 200;

FIG. 4 depicts a transconductance amplifier circuit 400 in accordance with an exemplary embodiment of the disclosure, which includes a voltage-to-current (V-to-I) circuit 402, and a current summing circuit 404 with high output impedance;

FIG. 5A, FIG. 5B, and FIG. 5C illustrate V-to-I circuit 500, 500′, and 500″ in accordance with exemplary embodiments of the disclosure;

FIG. 6A, FIG. 6B, and FIG. 6C show three types of current summing circuits which receive the differential currents Δi+ and Δi− from the sources of the n-channel output MOSs Mo1 and Mo2 of any V-to-I circuit of FIG. 5A, FIG. 5B, and FIG. 5C;

FIG. 7A, FIG. 7B, and FIG. 7C illustrate V-to-I circuit 700, 700′, and 700″ in accordance with exemplary embodiments of the disclosure;

FIG. 8A, FIG. 8B, and FIG. 8C show three types of current summing circuits which receive the differential currents Δi+ and Δi− from the sources of the n-channel output MOSs Mo1 and Mo2 of any V-to-I circuit of FIG. 7A, FIG. 7B, and FIG. 7C.

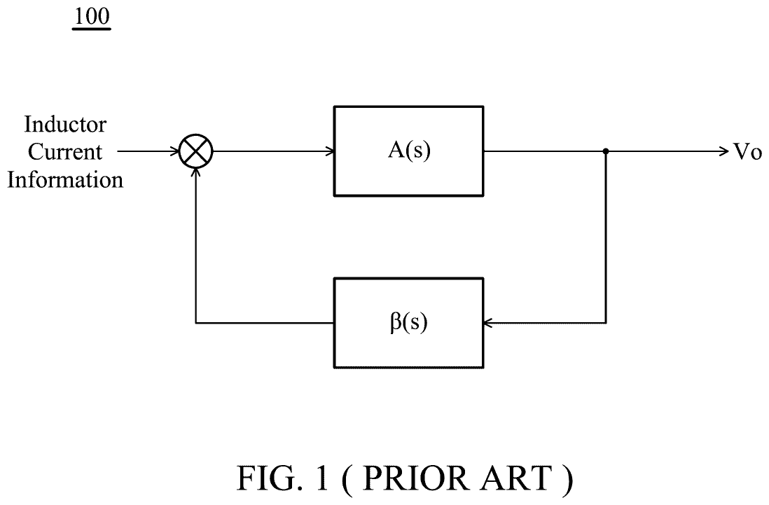

### DETAILED DESCRIPTION OF THE INVENTION

The following description enumerates various embodiments of the disclosure, but is not intended to be limited thereto. The actual scope of the disclosure should be defined according to the claims. The various blocks may be implemented by special circuits. The circuit components may be directly connected to each other without additional components as the circuit illustrated in the figures. Or, there may be some additional components coupled between the illustrated circuit components.

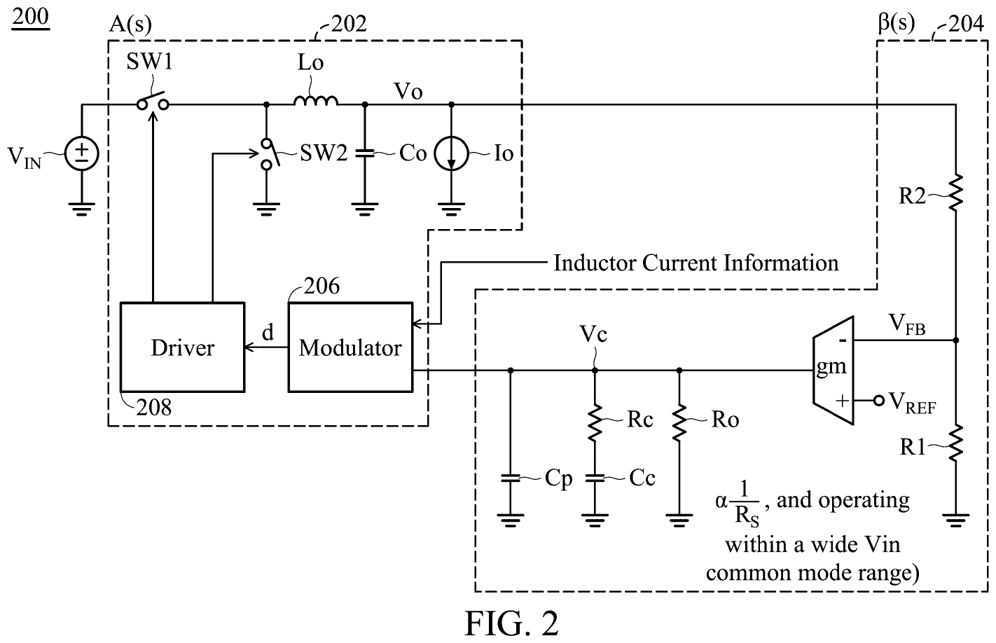

FIG. 2 depicts a switched-inductor based DC-DC converter 200 in accordance with an exemplary embodiment of the disclosure, which includes a basic switched-inductor DC-DC conversion circuit 202 (with a transfer function A(s)) and a type-II compensator circuit (with a transfer function(s)).

The basic switched-inductor DC-DC conversion circuit 202 includes an inductor Lo, a first switch SW1 operative to connect the input voltage V_{IN} to the inductor Lo to establish a charge path for the inductor Lo, and a second switch SW2 operative to connect the inductor Lo to the ground to establish a discharge path for the inductor Lo. The basic switched-inductor DC-DC conversion circuit 202 has a capacitor Co and a current source Io at its output stage. The basic switched-inductor DC-DC conversion circuit 202 further has a modulator 206 and a driver 208 for operating the first and second switches SW1 and SW2.

The modulator 206 receives inductor current information collected from the inductor Lo, and a compensation voltage Vc generated by the type-II compensator circuit 204, and thereby generates a control signal d (e.g., a PWM signal) to control the driver 208 to operate the first and second switches SW1 and SW2.

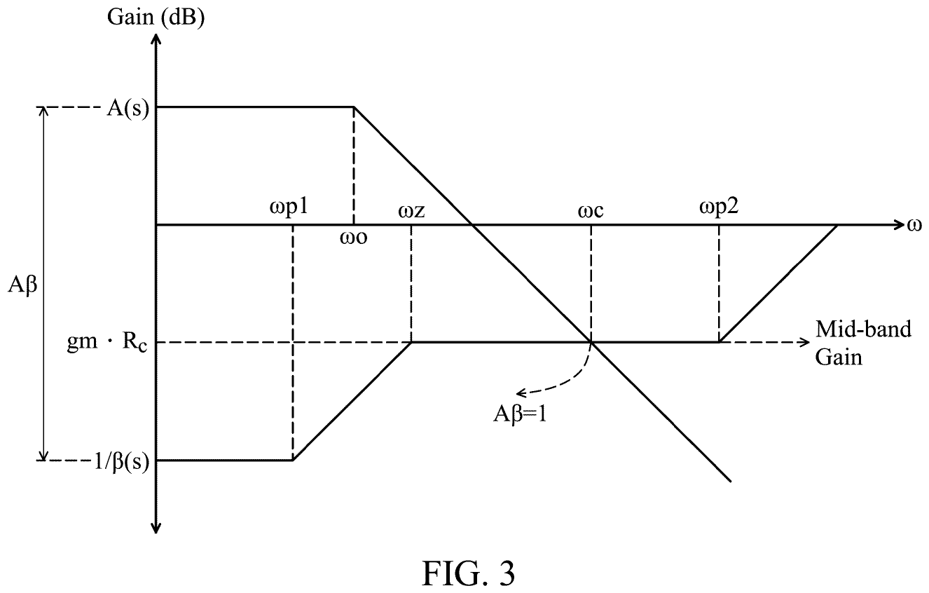

The type-II compensator circuit 204 includes a voltage divider R1 and R2, a transconductance amplifier circuit 210 receiving the feedback voltage VFB from the voltage divider R1 and R2 and a reference voltage Vref, a resistor Ro coupling the output terminal (Vc) of the transconductance amplifier circuit 210 to the ground, a compensation resistor Rc and a compensation capacitor Cc connected in series between the output terminal (Vc) of the transconductance amplifier circuit 210 and the ground, and a capacitor Cp coupling the output terminal (Vc) of the transconductance amplifier circuit 210 to the ground. The type-II compensator circuit 204 introduces two poles and one zero in the control scheme. Especially, the transconductance amplifier circuit 210 is designed to provide a transconductance gm that is proportional to 1/Rs, where Rs is a resistor coupled between the drains of the differential output MOSs of the transconductance amplifier circuit 210. Especially, the resistor type of Rs is the same as the resistor type of Rc (made by the same process). As presented in the following Bode diagram of FIG. 3, such a design makes the switched-inductor based DC-DC converter 200 being PVT insensitive. And, the transconductance amplifier circuit 210 has a special design for operating in a wide Vin common mode range with high linearity.

FIG. 3 is a Bode diagram of the switched-inductor based DC-DC converter 200. The transfer function(s) introduces a low-frequency pole ω1 (determined by the compensation capacitor Cc and the resistor Ro), a mid-frequency zero ωz (determined by the compensation capacitor Cc and the compensation resistor Rc), and a high-frequency pole ωp2 (determined by the capacitor Cp and the parallel resistance Rc//Ro). Due to the negative feedback design, the transfer function β(s) is inversed as 1/B(s). The crossover frequency depends on the mid-band gain (gₘ·R_{c}) of the type-II compensator circuit 204. In order to achieve PVT insensitive crossover frequency control, the mid-band gain (gₘ·R_{c}) of the type-II compensator circuit 204 needs to be insensitive to PVT variations. Generally, the compensation resistor R_{c} used in the type-II compensator circuit 204 has large process and temperature variations. In this disclosure, the transconductance gₘ of the transconductance amplifier circuit 210 is strongly proportional to 1/Rₛ where the resistor type of Rₛ is the same as R_{c}. The PVT insensitive mid-band gain control therefore is achieved.

In additional to the PVT insensitive features, the transconductance amplifier circuit 210 (gₘ∝1/Rₛ) further has some special designs to maintain its high linearity within a wide input common mode range. As the voltage used for modern technology getting lower, the output voltage programmable range of the switched-inductor based DC-DC converter 200 becomes much wider. The transconductance amplifier circuit 210 can properly deal with it.

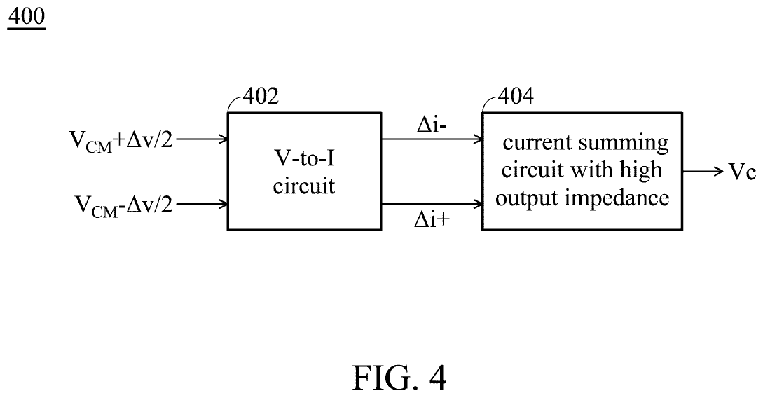

FIG. 4 depicts a transconductance amplifier circuit 400 in accordance with an exemplary embodiment of the disclosure, which includes a voltage-to-current (V-to-I) circuit 402, and a current summing circuit 404 with high output impedance. The V-to-I circuit 402 is a differential-in-and-differential-out circuit. The feedback voltage VFB and the reference voltage Vref at the input terminals of the transconductance amplifier circuit 210 of FIG. 2 are coupled to the V-to-I circuit 402 as the differential voltage input (V_{CM}+Δv/2) and (V_{CM}−Δv/2), and transformed to the differential current output Δi+ and Δi−. The current summing circuit 404 with high output impedance is a differential-in-and-single-out circuit, which transforms the differential current output Δi+ and Δi− received from the V-to-I circuit 402 to the amplified voltage Vc which is used for compensation in FIG. 2. In this disclosure, the V-to-I circuit 402 is specially designed.

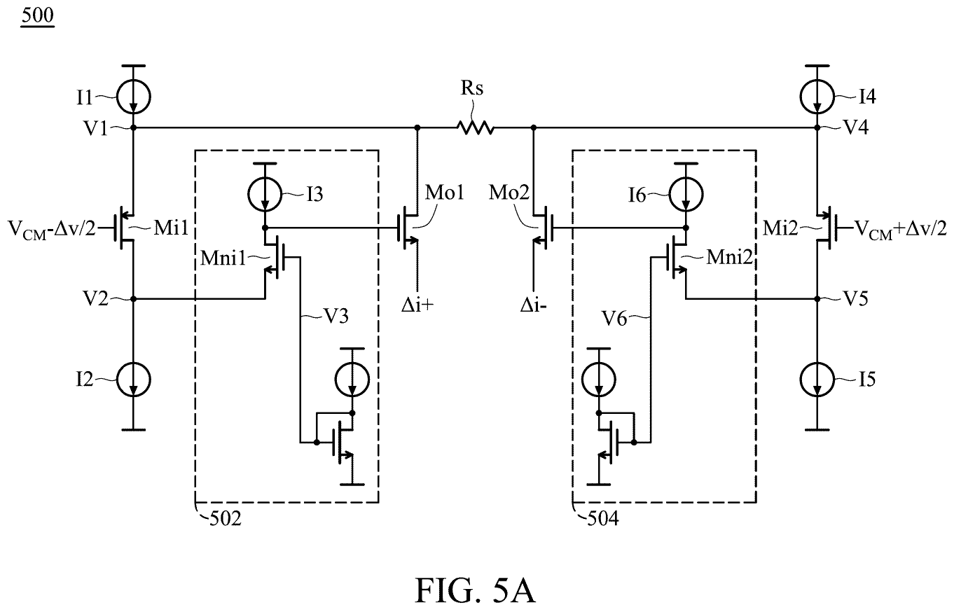

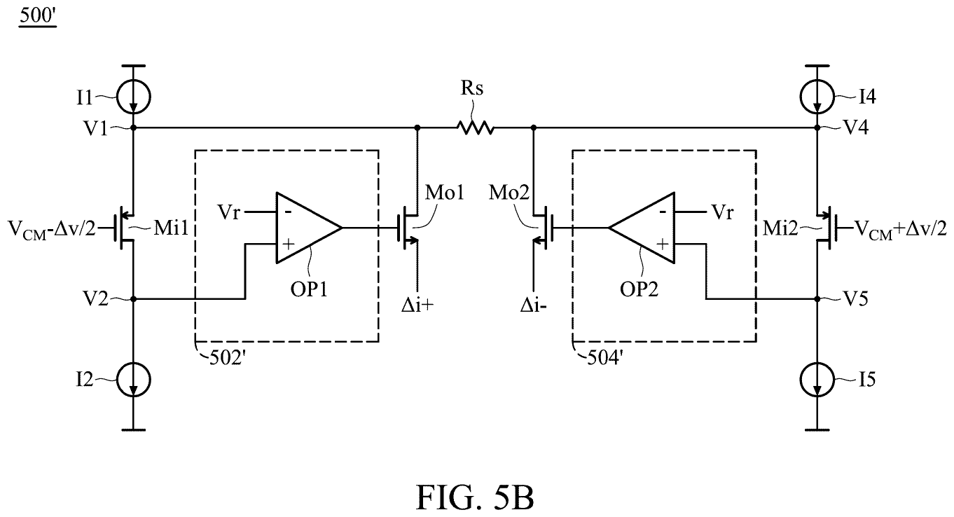

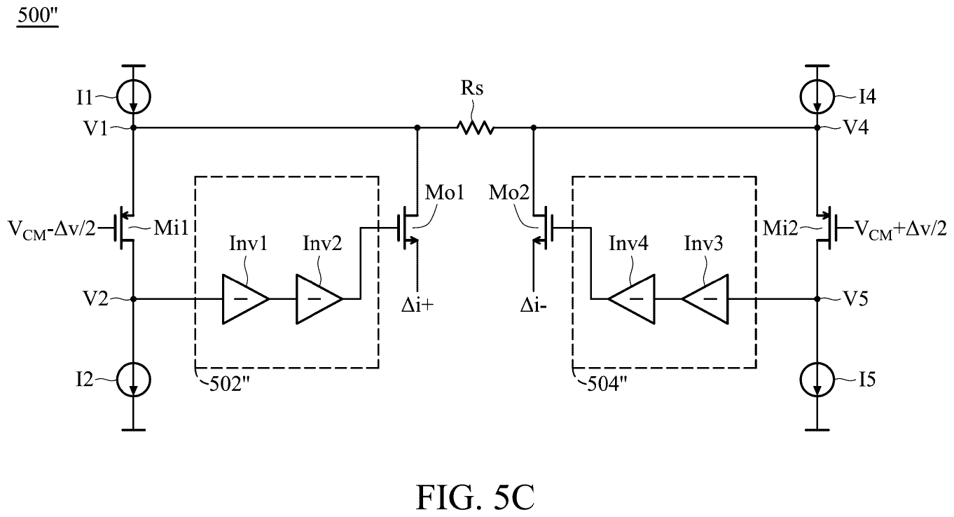

FIG. 5A illustrates a V-to-I circuit 500 in accordance with an exemplary embodiment of the disclosure, which includes input metal-oxide-semiconductor field-effect transistors (MOSs) Mi1 and Mi2 (p-channel MOSs in this case) having gates respectively receiving the differential voltages (V_{CM}+Δv/2) and (V_{CM}−Δv/2), output MOSs Mo1 and Mo2 (n-channel MOSs in this case) having drains respectively coupled to the sources of the input MOSs Mi1 and Mi2, a resistor Rs coupled between the drain of the output MOS Mo1 and the drain of the output MOS Mo2, a first non-inverting circuit 502 coupling the drain of the input MOS Mi1 to the gate of the output MOS Mo1, and a second non-inverting circuit 504 coupling the drain of the input MOS Mi2 to the gate of the output MOS Mo2. The differential currents Δi+ and Δi− are generated at the sources of the output MOSs Mo1 and Mo2. Due to the first non-inverting circuit 502, the voltage V2 at the drain of the input MOS Mi1 is not raised to a too high value, and so as the voltage V5 at the drain of the input MOS Mi2. Thus, the V-to-I circuit 500 operates in a wide input range with high linearity.

In FIG. 5A, the first non-inverting circuit 502 includes a non-inverting transform MOS Mni1 (an n-channel MOS in this case) and a current source I3. The drain of the input MOS Mi1 is coupled to the source of the non-inverting transform MOS Mni1. The drain of the non-inverting transform MOS Mni1 is coupled to the gate of the output MOS Mo1. The current source I3 is coupled to the drain of the non-inverting transform MOS Mni1. The voltage V2 is amplified by the non-inverting transform MOS MNI1 and outputs to the gate of the output MOS Mo1. The driving capability to the small resistor Rs (e.g., only N K ohms, where N is smaller than 10) is improved by the first non-inverting circuit 502. As shown, the gate of the non-inverting transform MOS Mni1 is biased by a bias voltage V3. An example of the bias circuit is shown in the figure.

The second non-inverting circuit 504 is in the similar structure, which includes a non-inverting transform MOS Mni2 (an n-channel MOS in this case) and a current source I6. The drain of the input MOS Mi2 is coupled to the source of the non-inverting transform MOS Mni2. The drain of the non-inverting transform MOS Mni2 is coupled to the gate of the output MOS Mo2. The current source I6 is coupled to the drain of the non-inverting transform MOS Mni2. The voltage V5 is amplified by the non-inverting transform MOS Mni2 and outputs to the gate of the output MOS Mo2. The driving capability to the small resistor Rs is improved by the second non-inverting circuit 504. As shown, the gate of the non-inverting transform MOS Mni2 is biased by a bias voltage V6. An example of the bias circuit is shown in the figure.

FIG. 5B illustrates a V-to-I circuit 500′ in accordance with another exemplary embodiment of the disclosure, which uses an operational amplifier OP1 to implement the first non-inverting circuit 502′, and an operational amplifier OP2 to implement the second non-inverting circuit 504′. As shown, the drain of the input MOS Mi1 is coupled to the positive input terminal of the operational amplifier OP1. The operation amplified OP1 has a negative input terminal receiving a reference voltage Vr, and an output terminal coupled to the gate of the output MOS Mo1. As for the second non-inverting circuit 504′, the drain of the input MOS Mi2 is coupled to the positive input terminal of the operational amplifier OP2. The operation amplified OP2 has a negative input terminal receiving a reference voltage Vr, and an output terminal coupled to the gate of the output MOS Mo2.

FIG. 5C illustrates a V-to-I circuit 500″ in accordance with another exemplary embodiment of the disclosure, which uses two inverting amplifiers Inv1 and Inv2 coupled in series to implement the first non-inverting circuit 502″, and two inverting amplifiers Inv3 and Inv4 coupled in series to implement the second non-inverting circuit 504″. As shown, the drain of the input MOS Mi1 is coupled to the input terminal of the inverting amplifier Inv1, and the output terminal of the inverting amplifier Inv2 is coupled to the gate of the output MOS Mo1. As for the second non-inverting circuit 504″, the drain of the input MOS Mi2 is coupled to the input terminal of the inverting amplifier Inv3, and the output terminal of the inverting amplifier Inv4 is coupled to the gate of the output MOS Mo2.

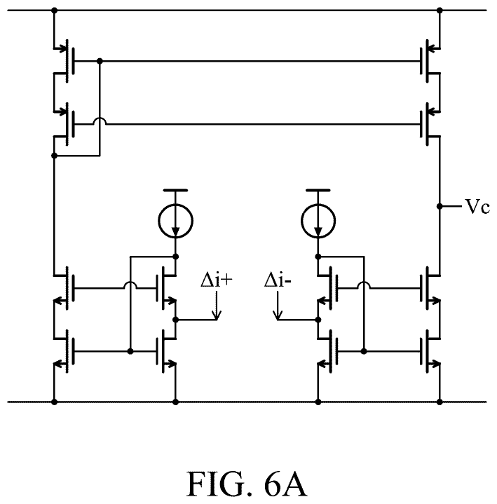

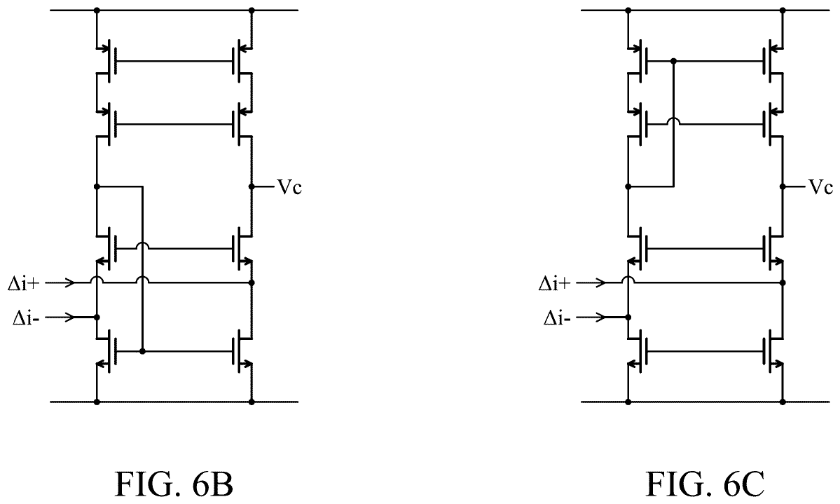

The current summing circuit 404 may be implemented in many ways. FIG. 6A, FIG. 6B, and FIG. 6C show three types of current summing circuits which receive the differential currents Δi+ and Δi− from the sources of the n-channel output MOSs Mo1 and Mo2 of any V-to-I circuit of FIG. 5A, FIG. 5B, and FIG. 5C. FIG. 6A shows a current mirror operational transconductance amplifier (OTA). FIG. 6B and 6C show two cascade structures.

In some examples, the input MOSs of the V-to-I circuit 402 are n-channel MOSs, the output MOSs of the V-to-I circuit 402 are p-channel MOSs.

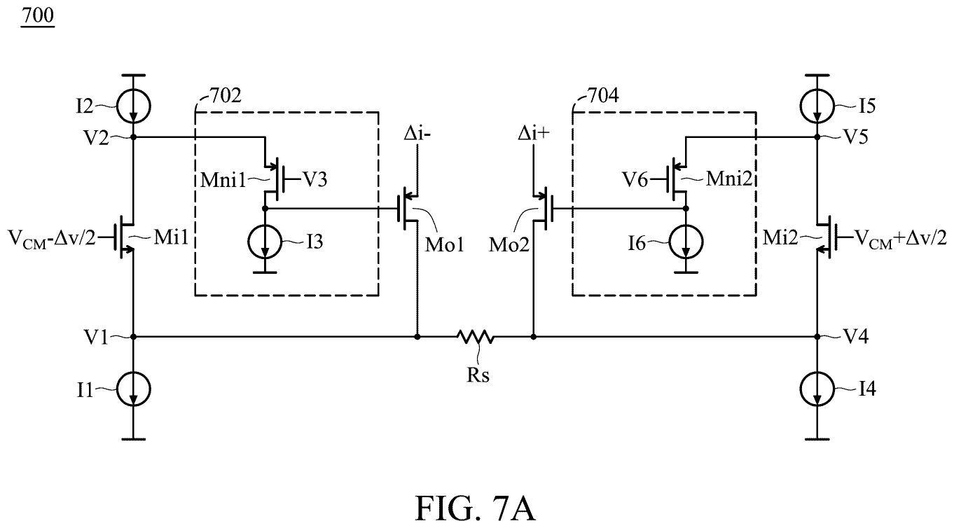

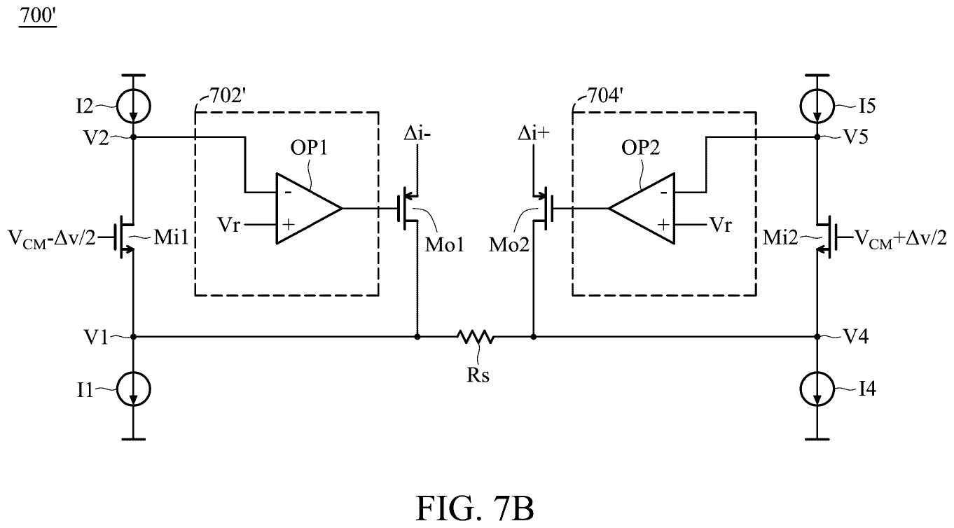

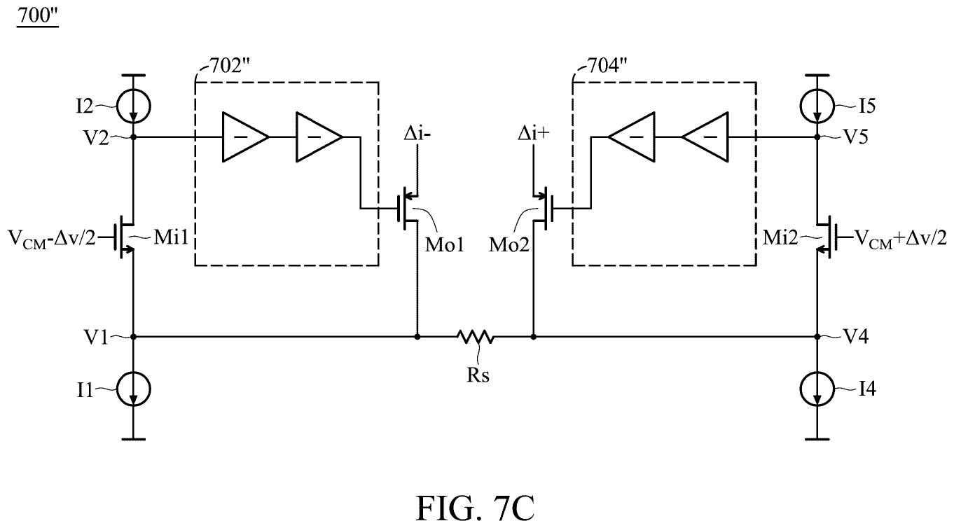

FIG. 7A illustrates a V-to-I circuit 700 with n-channel input MOSs Mi1 and Mi2, p-channel output MOSs Mo1 and Mo2. The first non-inverting circuit 702 uses a p-channel non-inverting transform MOS Mni1. The second non-inverting circuit 704 uses a p-channel non-inverting transform MOS Mni2.

FIG. 7B illustrates a V-to-I circuit 700′ with n-channel input MOSs Mi1 and Mi2, and p-channel output MISs Mo1 and Mo2. The first operational amplifier OP1 implementing the first non-inverting circuit 702′ has a negative input terminal coupled to the drain of the input MOS Mi1, and a positive input terminal receiving a reference voltage Vr. The second operational amplifier OP2 implementing the second non-inverting circuit 704′ has a negative input terminal coupled to the drain of the input MOS Mi2, and a positive input terminal receiving a reference voltage Vr.

FIG. 7C illustrates a V-to-I circuit 700″ with n-channel input MOSs Mi1 and Mi2, and p-channel output MOSs Mo1 and Mo2. The first non-inverting circuit 702″ uses two inverting amplifiers connected in series between the drain of the input MOS Mi1 and the gate of the output MOS Mo1. The second non-inverting circuit 704″ uses two inverting amplifiers connected in series between the drain of the input MOS Mi2 and the gate of the output MOS Mo2.

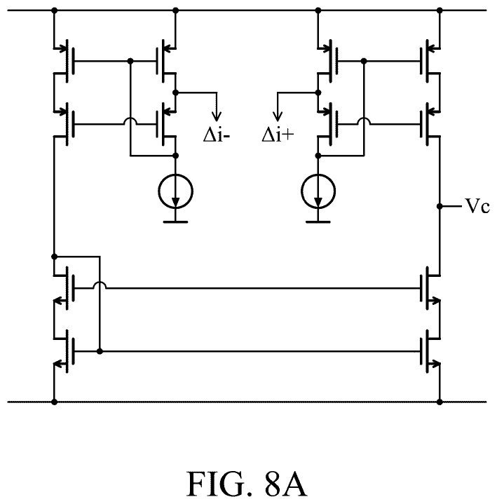

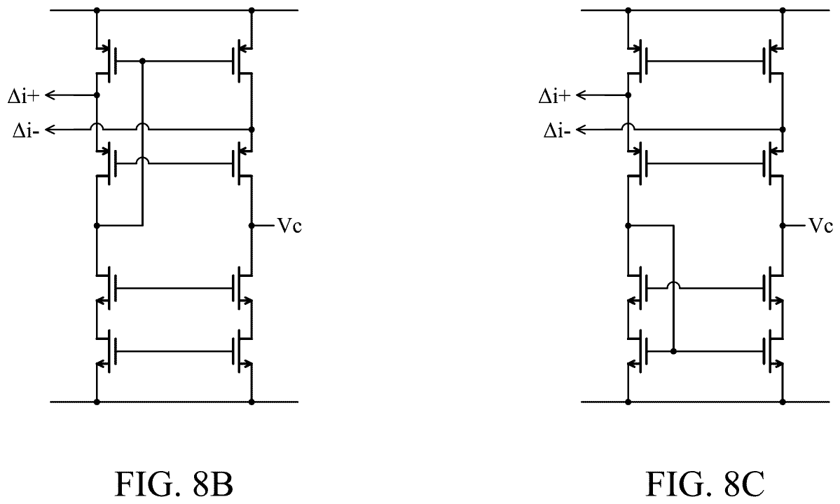

FIG. 8A, FIG. 8B, and FIG. 8C show three types of current summing circuits which receive the differential currents Δi+ and Δi− from the sources of the p-channel output MOSs Mo1 and Mo2 of any V-to-I circuit of FIG. 7A, FIG. 7B, and FIG. 7C. FIG. 8A shows a current mirror OTA. FIG. 8B and 8C show two cascade structures.

Any super source follower structure with the non-inverting circuits between the input MOSs and the output MOSs should be considered within the scope of the invention.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A transconductance amplifier circuit, comprising:
a voltage-to-current circuit, including first input metal-oxide-semiconductor field-effect transistor (MOS), a second input MOS, a first output MOS, a second output MOS, a resistor, a first non-inverting circuit, and a second non-inverting circuit;
wherein:
a differential voltage input is coupled to the voltage-to-current circuit through a gate of the first input MOS and a gate of the second input MOS;
a differential current output is generated at a source of the first output MOS and a source of the second output MOS;
the resistor is coupled between a drain of the first output MOS and a drain of the second output MOS;
the drain of the first output MOS is coupled to a source of the first input MOS, and the drain of the second output MOS is coupled to a source of the second input MOS; and
a drain of the first input MOS is coupled to a gate of the first output MOS through the first non-inverting circuit, and a drain of the second input MOS is coupled to a gate of the second output MOS through the second non-inverting circuit.

2. The transconductance amplifier circuit as claimed in claim 1, wherein:
the first input MOS and the second input MOS are p-channel MOSs; and
the first output MOS and the second output MOS are n-channel MOSs.

3. The transconductance amplifier circuit as claimed in claim 2, wherein:
the first non-inverting circuit includes a first non-inverting transform MOS that is an n-channel MOS having a source coupled to the drain of the first input MOS and a drain coupled to the gate of the first output MOS.

4. The transconductance amplifier circuit as claimed in claim 2, wherein:
the second non-inverting circuit includes a second non-inverting transform MOS that is an n-channel MOS having a source coupled to the drain of the second input MOS and a drain coupled to the gate of the second output MOS.

5. The transconductance amplifier circuit as claimed in claim 2, wherein:
the first non-inverting circuit includes a first operational amplifier having a positive input terminal coupled to the drain of the first input MOS, a negative input terminal coupled to a reference voltage, and an output terminal coupled to the gate of the first output MOS.

6. The transconductance amplifier circuit as claimed in claim 2, wherein:
the second non-inverting circuit includes a second operational amplifier having a positive input terminal coupled to the drain of the second input MOS, a negative input terminal coupled to a reference voltage, and an output terminal coupled to the gate of the second output MOS.

7. The transconductance amplifier circuit as claimed in claim 1, wherein:
the first input MOS and the second input MOS are n-channel MOSs; and
the first output MOS and the second output MOS are p-channel MOSs.

8. The transconductance amplifier circuit as claimed in claim 7, wherein:
the first non-inverting circuit includes a first non-inverting transform MOS that is a p-channel MOS having a source coupled to the drain of the first input MOS and a drain coupled to the gate of the first output MOS.

9. The transconductance amplifier circuit as claimed in claim 7, wherein:
the second non-inverting circuit includes a second non-inverting transform MOS that is a p-channel MOS having a source coupled to the drain of the second input MOS and a drain coupled to the gate of the second output MOS.

10. The transconductance amplifier circuit as claimed in claim 7, wherein:
the first non-inverting circuit includes a first operational amplifier having a negative input terminal coupled to the drain of the first input MOS, a positive input terminal coupled to a reference voltage, and an output terminal coupled to the gate of the first output MOS.

11. The transconductance amplifier circuit as claimed in claim 7, wherein:
the second non-inverting circuit includes a second operational amplifier having a negative input terminal coupled to the drain of the second input MOS, a positive input terminal coupled to a reference voltage, and an output terminal coupled to the gate of the second output MOS.

12. The transconductance amplifier circuit as claimed in claim 1, wherein:
the first non-inverting circuit includes two inverting amplifiers coupled in series between the drain of the first input MOS and the gate of the first output MOS.

13. The transconductance amplifier circuit as claimed in claim 1, wherein:
the second non-inverting circuit includes two inverting amplifiers coupled in series between the drain of the second input MOS and the gate of the second output MOS.

14. The transconductance amplifier circuit as claimed in claim 1, further comprising:
a current summing circuit, receiving the differential current output from the voltage-to-current circuit, and generating an amplified voltage.

15. A DC-DC converter, comprising:
a basic switched-inductor DC-DC conversion circuit; and
a type-II compensator circuit using the transconductance amplifier circuit as claimed in claim 14,
wherein:
the type-II compensator circuit is coupled to the basic switched-inductor DC-DC conversion circuit to form a negative feedback control loop, and introduces two poles and one zero; and
the resistor of the transconductance amplifier circuit and a compensation resistor are manufactured using the same type of process.
